(19) United States
(12) Patent Application Publication
(10) Pub. No.: US 2026/0342292 A1
(43) Pub. Date: Oct. 29, 2026

(54) PVT INSENSITIVE RING AMPLIFIER BASED PGA FOR SILICON MICROPHONES

(71) Applicant: Infineon Technologies AG, Neubiberg (DE)

(72) Inventors: Fulvio Ciciotti, Bad Bleiberg (AT); Jose Luis Ceballos, Villach (AT); Christopher Igor Rogi, Villach (AT)

(21) Appl. No.: 19/188,555

(22) Filed: Apr. 24, 2025

(51) Int. Cl. H03F 3/183; H04R 3/00; H04R 19/04

(52) U.S. Cl. CPC H03F 3/183; H04R 3/00; H04R 19/04; H03F 2200/03; H04R 2201/003

(57) ABSTRACT

A ring amplifier includes a plurality of serially coupled inverters coupled between an input node and an output node, wherein a first inverter of the plurality of serially coupled inverters comprises a bias node; a dead zone generator coupled to the plurality of serially coupled inverters; and a bias generator coupled to the bias node of the first inverter, the bias generator controlling a current through the first inverter.

### TECHNICAL FIELD

The present invention relates generally to a process, voltage, and temperature (PVT) ring amplifier based programmable gain amplifier (PGA) for silicon microphones, and to a corresponding system and method.

### BACKGROUND

Ring amplifiers are widely used in modern integrated circuits due to their high gain, low power consumption, and small area. However, their performance can be significantly affected by process, voltage, and temperature (PVT) variations. PVT variations can cause changes in the ring amplifier's current consumption, gain, bandwidth, and stability, leading to reduced performance and reliability. Different compensation techniques are known in the art, but focus on improving the ring amplifier stability by addressing the “dead zone” biasing, settling response and overall ring amplifier stability. Prior art solutions do not, however, address controlling amplifier current consumption, which can vary widely due to the intrinsic variations of the inverter-based structure. A stable over PVT amplifier current is essential in applications in which noise and power are the major design constraints.

### SUMMARY

According to an embodiment, a ring amplifier comprises a plurality of serially coupled inverters coupled between an input node and an output node, wherein a first inverter of the plurality of serially coupled inverters comprises a bias node; a dead zone generator coupled to the plurality of serially coupled inverters; and a bias generator coupled to the bias node of the first inverter, the bias generator configured to control a current through the first inverter.

According to an embodiment, a method of operating a ring amplifier comprises a plurality of serially coupled inverters coupled between an input node and an output node, wherein a first inverter of the plurality of serially coupled inverters comprises a bias node, the method comprising generating a reference voltage; and applying the reference voltage to the bias node to provide a controlled current through the first inverter.

According to an embodiment, a system comprises a first ring amplifier comprising a first bias node; and a reference current source coupled to the first bias node to provide a controlled current through a first inverter of the first ring amplifier.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a schematic diagram of a self-biased ring amplifier, according to the prior art;

FIG. 2A is a schematic diagram of a controlled-current bias ring amplifier, according to an embodiment;

FIG. 2B is a schematic diagram of a bandgap core circuit for generating a reference voltage, according to an embodiment;

FIG. 2C is a schematic diagram of a PVT current source including the bandgap core circuit and a voltage-to-current generator for use in the controlled-current bias ring amplifier of FIG. 2A; and

FIG. 3 is a schematic diagram of a silicon microphone system using two controlled-current bias ring amplifiers of FIG. 2A, according to an embodiment.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same or similar elements have been designated by corresponding references in the different drawings if not stated otherwise.

According to an embodiment, a ring amplifier uses a current source of voltage reference generator to stabilize the current of a first stage inverter (which typically represents the majority of the total current consumption because of noise constraints). In particular, the ring amplifier includes a high impedance biasing network acting on the gate of a PMOS transistor or NMOS transistor in the first inverter. The PMOS gate voltage or NMOS gate voltage sets the desired bias current through the first inverter and tracks PVT variations, maintaining stable power and performance of the ring amplifier. The ring amplifier, corresponding method, and a silicon microphone system are all explained in further detail below.

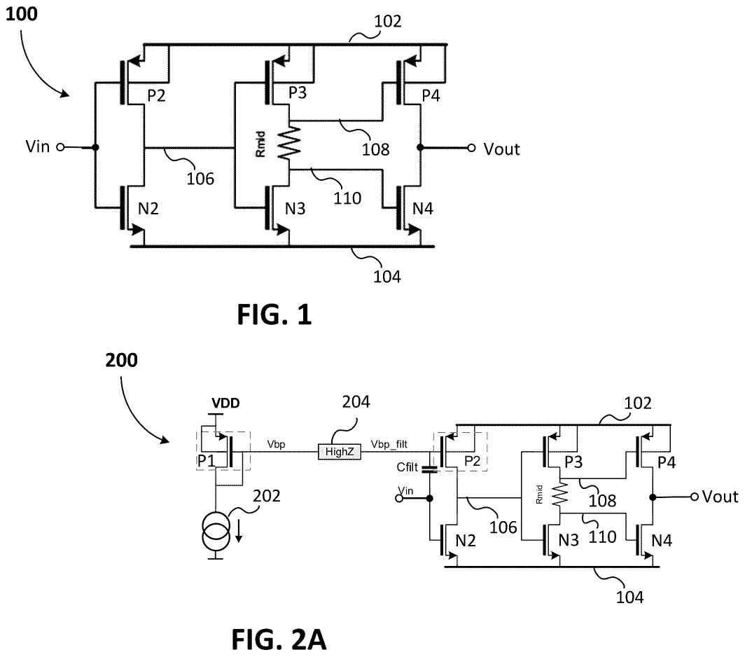

FIG. 1 is a schematic diagram of a self-biased ring amplifier 100, according to the prior art. Self-biased ring amplifier comprises a chain of three inverters P2/N2, P3/N3, and P4/N4, wherein P2, P3, and P4 are PMOS transistors, and wherein N2, N3, and N4 are NMOS transistors. The inverters are coupled between a first supply voltage rail 102 and a second supply voltage rail 104. In FIG. 1, the body contact of PMOS transistors P2, P3, and P4 are coupled to the first supply voltage rail 102. The input of inverter P2/N2 is coupled to the Vin input node, and the output of inverter P2/N2 is coupled to node 106. The input of inverter P3/N3 is coupled to node 106. The drain of transistor P3 is coupled to node 108 and the drain of transistor N3 is coupled to node 110. The gate of transistor P4 is coupled to node 108 and the gate of transistor N4 is coupled to node 110. The output of inverter P4/N4 is coupled to the Vout output node. A “dead zone” is achieved by resistor Rmid, which is coupled between nodes 108 and 110. The “dead zone” effectively creates the voltage necessary to achieve a small quiescent current in the output stage. This, in turn, effectively creates a dominant pole at the output, which dynamically stabilizes the negative feedback loop (not shown in FIG. 1). The current consumption of self-biased ring amplifier 100, however, is not well controlled in this implementation.

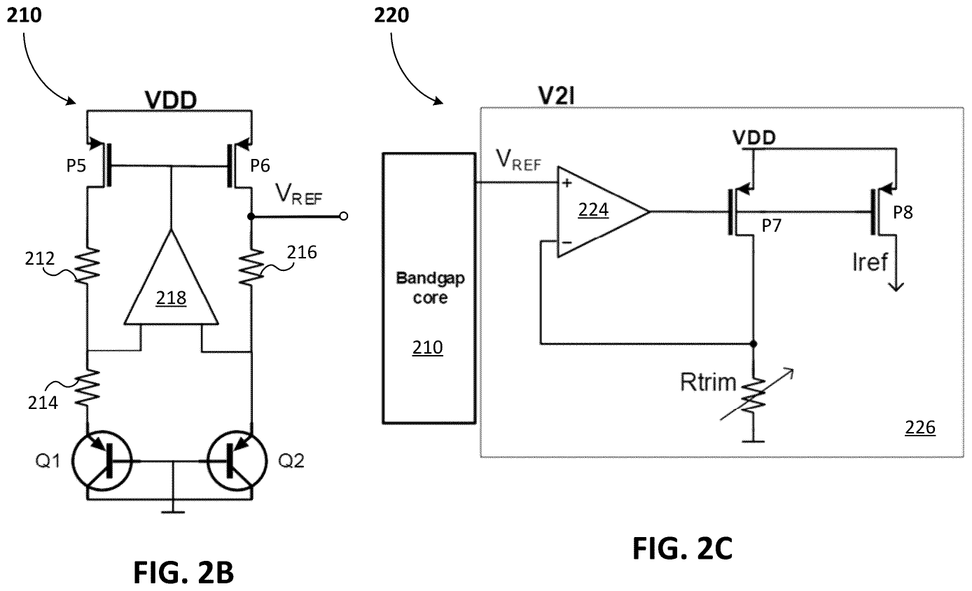

FIG. 2A is a schematic diagram of a controlled-current bias ring amplifier 200, according to an embodiment. The controlled-current bias ring amplifier 200 includes a ring amplifier including inverters P2/N2, P3/N3, P4/N4, and resistor Rmid, all previously described, as well as a stable reference current source 202 and a PMOS transistor P1 in a diode configuration. The stable reference current source 202 is used to generate the desired gate voltage Vbp that satisfies current/noise tradeoffs (dominated by the first inverter stage P2/N2). Voltage Vbp is applied to the gate of transistor P2 via a high ohmic resistor 204 (Vpb_filt). The input of the controlled-current bias ring amplifier 200 (Vin) is decoupled from Vpb_filt by capacitor Cfilt. A stable bandgap generated current and matching between PMOS transistor P2 and reference diode (PMOS transistor P1) ensures that Vbp_filt tracks any process, voltage, or temperature (PVT) variation, maintaining stable the current in inverter (P2/N2). In other words, PMOS transistor P1 and PMOS transistor P2 are in a current mirror configuration, and the inclusion of high ohmic resistor 204 does not substantially affect this configuration due to the low gate currents.

FIG. 2B is a schematic diagram of a bandgap core circuit 210 for generating a reference voltage. The bandgap core circuit 210 comprises PMOS transistor P5 and PMOS transistor P6, wherein the sources are coupled together and to VDD, and the gates are coupled together. Bandgap core circuit 210 also includes a resistor divider in the current path of PMOS transistor P5 comprising resistor 212 and resistor 214. The output of the resistor divider is coupled to a first input of amplifier 218. A resistor 216 in the current path of PMOS transistor P6 is coupled to a second input of amplifier 218. The output of amplifier 218 is coupled to the gate of PMOS transistor P5 and to the gate of PMOS transistor P6. Bandgap core circuit 210 also includes a PNP bipolar transistor Q1 and a PNP transistor Q2 in a coupled diode configuration. PNP bipolar transistor Q1 is coupled between resistor 214 and ground, and PNP bipolar transistor Q2 is coupled between resistor 216 and ground. The stable reference voltage V_{REF} is generated at the junction between the drain of PMOS transistor P6 and resistor 216.

FIG. 2C is a schematic diagram of a reference current source including the bandgap core circuit 210 and a voltage-to-current (V2I) generator 226 for use in the controlled-current bias ring amplifier 200 of FIG. 2A. The bandgap core circuit 210 is described above. In an embodiment, the V2I generator 226 comprises an operational amplifier 224, PMOS transistor P7, PMOS transistor P8, and trim resistor R_{TRIM}. The positive input of operational amplifier 224 receives the V_{REF} voltage, and provides an output reference current I_{REF} at the drain of PMOS transistor P8. The equation for the output reference current is I_{REF}=V_{REF}/R_{TRIM}. The gates of PMOS transistor P7 and PMOS transistor P8 are coupled together, and the emitters are coupled to VDD. The drain of PMOS transistor P7 is coupled to resistor RTRIM and to the negative input of operational amplifier 224. PMOS transistor P7 generally corresponds to PMOS transistor P1 in FIG. 2A, and PMOS transistor P8 generally corresponds to PMOS transistor P2 in FIG. 2A.

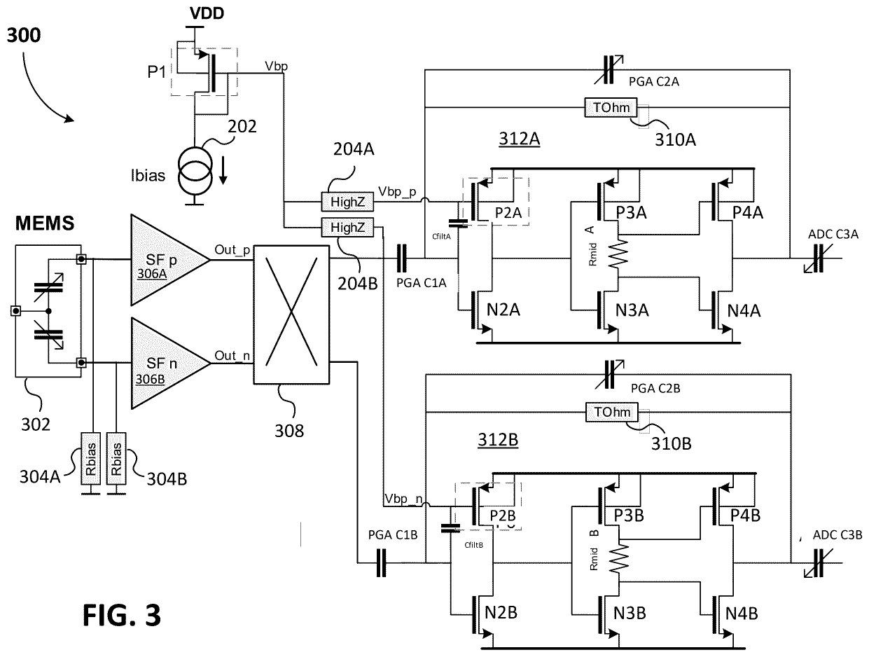

FIG. 3 is a schematic diagram of a silicon microphone system 300 using two controlled-current bias ring amplifiers of FIG. 2A, according to an embodiment. FIG. 3 further shows the complete PGA structure used in a microphone readout system, from the microelectromechanical system (MEMS) biasing and source follower buffers, to the implemented pseudo differential ring amplifier-based PGA, which comprises a first ring amplifier 312A and a second ring amplifier 312B.

The first ring amplifier 312A comprises serially coupled inverters P2A/N2A, P3A/N3A, P4A/N4A, and resistor RmidA, and a feedback path including a high impedance resistor 310A and an adjustable capacitor C2A. The first ring amplifier 312A also includes an input capacitor C1A. The output of the first ring amplifier 312A is coupled to a first analog-to-digital converter (ADC), wherein only the adjustable input capacitor C3A for the first ADC is shown in FIG. 3. In some embodiments, a single differential input ADC may be also used instead of a separate first ADC and a second ADC.

Similarly, the second ring amplifier 312B comprises serially coupled inverters P2B/N2B, P3B/N3B, P4B/N4B, and resistor RmidB, and a feedback path including a high impedance resistor 310B and an adjustable capacitor C2B. The second ring amplifier 312B also includes an input capacitor C1B. The output of the second ring amplifier 312B is coupled to a second analog-to-digital converter (ADC), wherein only the adjustable input capacitor C3B for the second ADC is shown in FIG. 3. As stated above, a single differential ADC may also be used instead of a separate first ADC and a second ADC.

The silicon microphone system 300 also includes the stable current source 202 coupled to the diode configured PMOS transistor P1 at node Vbp as previously discussed. The Vbp node is coupled to the Vbp_p bias node of the first ring amplifier 312A through high impedance resistor 204A. The Vbp bias node is coupled to the input of the first ring amplifier 312A through capacitor CfiltA. The Vbp node is also coupled to the Vbp_n bias node of the second ring amplifier 312B through high impedance resistor 204B. The Vbp bias node is also coupled to the input of the second ring amplifier 312B through capacitor CfiltB.

Silicon microphone system 300 includes a differential MEMS device 302 having a first output coupled to a first biasing resistor 304A and the input of a first source follower 306A, and a second output coupled to a second biasing resistor 304B and the input of a second source follower 306B. A chopper 308 has a first input coupled to a first output (Out_p) of the first source follower 306A and a second input coupled to a second output (Out_n) of the second source follower 306B. The first output of chopper 308 is coupled to capacitor C1A and the second output of chopper 308 is coupled to capacitor C1B.

In summary, a ring amplifier 200 as shown in FIG. 2A comprises a plurality of serially coupled inverters P2/N2, P3/N3, P4/N4 coupled between an input node Vin and an output node Vout, wherein a first inverter P2/N2 of the plurality of serially coupled inverters comprises a bias node Vbp_filt; a dead zone generator Rmid coupled to the plurality of serially coupled inverters; and a bias generator including current source 202 and PMOS transistor P1 coupled to the bias node of the first inverter, the bias generator configured to control a current through the first inverter. The ring amplifier 200 further comprises a resistor 204 interposed between the bias generator and the bias node of the first inverter; and a capacitor Cfilt coupled between the bias node of the first inverter and the input node. In an embodiment, the bias generator comprises a bandgap circuit 210. Resistor 204 comprises at least one transistor biased in a cutoff region in an embodiment. In some embodiments, the dead zone generator Rmid is coupled to an inverter of the plurality of serially coupled inverters different from the first inverter, and can comprise a resistor or a diode circuit. In FIG. 2, the plurality of serially coupled inverters includes a total of three serially coupled inverters, although different numbers of inverters can be used in other embodiments.

In summary, a method of operating a ring amplifier 200 comprising a plurality of serially coupled inverters P2/N2, P3/N3, P4/N4 coupled between an input node Vin and an output node Vout, wherein a first inverter P2/N2 of the plurality of serially coupled inverters comprises a bias node Vbp_filt, comprises generating a reference voltage Vbp; and applying the reference voltage Vbp to the bias node Vbp_filt to provide a controlled current through the first inverter. In an embodiment applying the reference voltage comprises applying the reference voltage Vbp via a resistor 204 coupled to the bias node Vpb_filt and coupling a voltage at the input node Vin to the bias node Vpb_filt via a capacitor Cfilt. In an embodiment generating the reference voltage Vbp comprises generating the reference voltage with a bandgap circuit 210. In some embodiments, resistor 204 comprises at least one transistor biased in a cutoff region. In some embodiments the method includes generating a dead zone region in a DC transfer characteristic of the plurality of serially coupled inverters using a resistor Rmid, transistor or diode circuit coupled to an intermediate inverter of the plurality of serially coupled inverters.

In summary, a system 300 shown in FIG. 3 comprises a first ring amplifier 312A comprising a first bias node Vbp_p; and a reference current source 202 coupled to the first bias node Vbp_p to provide a controlled current through a first inverter P2A/N2A of the first ring amplifier 312A, according to an embodiment. The system 300, further comprises a first resistor interposed 204A between the reference current source 202 and the first bias node Vbp_p; and a first filter capacitor CfiltA coupled between the first bias node Vbp_p and a first input node of the first ring amplifier 312A. The system further comprises a first input capacitor C1A coupled to the first input node, and a first adjustable feedback capacitor C2A coupled between the first input node and an output node of the first ring amplifier. System 300 further comprising a first adjustable analog-to-digital converter (ADC) input capacitor C3A coupled to the output node of the first ring amplifier 312A. System 300 also comprises a second ring amplifier 312B comprising a second bias node Vbp_n coupled to the reference current source 202 to provide a stable current through the first inverter P2B/N2B of the second ring amplifier 312B. System 300 further comprises a chopper 308 coupled to a first input node of the first ring amplifier 312A and to a second input node of the second ring amplifier 312B, a first source follower circuit 306A and a second source follower circuit 306B coupled to the chopper 308, and a microelectromechanical system (MEMS) device 302 coupled to the first source follower circuit 306A and to the second source follower circuit 306B. Capacitors C3A and C3B may also be coupled to the differential input of a single differential ADC in some embodiments.

In embodiments, the PMOS or NMOS transistor gate of the first inverter can be used as a bias node. Biasing both the PMOs and NMOS transistor gates can also be used. However, in the case where both transistor gates are used, a DC output voltage regulation loop is required to set the operating point. The PMOS or NMOS transistor gate of subsequent inverters can also be used as bias nodes in some embodiments.

In some embodiments where very low supply voltages are not required a cascode PMOS transistor configuration or a cascode NMOS transistor configuration can be implemented to separate the bias and input nodes. Other circuit variations can also be used to control the current through the first inverter of the ring amplifier core.

Example embodiments of the present invention are summarized here. Other embodiments can also be understood from the entirety of the specification and the claims filed herein.

Example 1. According to an embodiment, a ring amplifier comprises a plurality of serially coupled inverters coupled between an input node and an output node, wherein a first inverter of the plurality of serially coupled inverters comprises a bias node; a dead zone generator coupled to the plurality of serially coupled inverters; and a bias generator coupled to the bias node of the first inverter, the bias generator configured to control a current through the first inverter.

Example 2. The ring amplifier of Example 1, further comprising a resistor interposed between the bias generator and the bias node of the first inverter; and a capacitor coupled between the bias node of the first inverter and the input node.

Example 3. The ring amplifier of any of the above examples, wherein the bias generator comprises a bandgap circuit.

Example 4. The ring amplifier of any of the above examples, wherein the resistor comprises at least one transistor biased in a cutoff region.

Example 5. The ring amplifier of any of the above examples, wherein the dead zone generator is coupled to an inverter of the plurality of serially coupled inverters different from the first inverter.

Example 6. The ring amplifier of any of the above examples, wherein the dead zone generator comprises a resistor or a diode circuit.

Example 7. The ring amplifier of any of the above examples, wherein the plurality of serially coupled inverters includes a total of three serially coupled inverters.

Example 8. According to an embodiment, a method of operating a ring amplifier comprising a plurality of serially coupled inverters coupled between an input node and an output node, wherein a first inverter of the plurality of serially coupled inverters comprises a bias node, wherein the method comprises generating a reference voltage; and applying the reference voltage to the bias node to provide a controlled current through the first inverter.

Example 9. The method of Example 8, wherein applying the reference voltage comprises applying the reference voltage via a resistor coupled to the bias node and coupling a voltage at the input node to the bias node via a capacitor.

Example 10. The method of any of the above examples, wherein generating the reference voltage comprises generating the reference voltage with a bandgap circuit.

Example 11. The method of any of the above examples, wherein the resistor comprises at least one transistor biased in a cutoff region.

Example 12. The method of any of the above examples, further comprising generating a dead zone region in a DC transfer characteristic of the plurality of serially coupled inverters using a resistor, transistor or diode circuit coupled to an intermediate inverter of the plurality of serially coupled inverters.

Example 13. According to an embodiment, a system comprises a first ring amplifier comprising a first bias node; and a reference current source coupled to the first bias node to provide a controlled current through a first inverter of the first ring amplifier.

Example 14. The system of Example 13, further comprising a first resistor interposed between the reference current source and the first bias node; and a first filter capacitor coupled between the first bias node and a first input node.

Example 15. The system of any of the above examples, further comprising a first input capacitor coupled to the first input node, and a first adjustable feedback capacitor coupled between the first input node and an output node of the first ring amplifier.

Example 16. The system of any of the above examples, further comprising a first adjustable analog-to-digital converter (ADC) input capacitor coupled to the output node of the first ring amplifier.

Example 17. The system of any of the above examples further comprising a second ring amplifier comprising a second bias node coupled to the reference current source to provide a stable current through the first inverter of the second ring amplifier.

Example 18. The system of any of the above examples, further comprising a chopper coupled to a first input node of the first ring amplifier and to a second input node of the second ring amplifier.

Example 19. The system of any of the above examples, further comprising a first source follower circuit and a second source follower circuit coupled to the chopper.

Example 20. The system of any of the above examples, further comprising a microelectromechanical system (MEMS) device coupled to the first source follower circuit and to the second source follower.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A ring amplifier comprising:
a plurality of serially coupled inverters coupled between an input node and an output node, wherein a first inverter of the plurality of serially coupled inverters comprises a bias node;
a dead zone generator coupled to the plurality of serially coupled inverters; and
a bias generator coupled to the bias node of the first inverter, the bias generator configured to control a current through the first inverter.

2. The ring amplifier of claim 1, further comprising:
a resistor interposed between the bias generator and the bias node of the first inverter; and
a capacitor coupled between the bias node of the first inverter and the input node.

3. The ring amplifier of claim 1, wherein the bias generator comprises a bandgap circuit.

4. The ring amplifier of claim 2, wherein the resistor comprises at least one transistor biased in a cutoff region.

5. The ring amplifier of claim 1, wherein the dead zone generator is coupled to an inverter of the plurality of serially coupled inverters different from the first inverter.

6. The ring amplifier of claim 5, wherein the dead zone generator comprises a resistor or a diode circuit.

7. The ring amplifier of claim 1, wherein the plurality of serially coupled inverters includes a total of three serially coupled inverters.

8. A method of operating a ring amplifier comprising a plurality of serially coupled inverters coupled between an input node and an output node, wherein a first inverter of the plurality of serially coupled inverters comprises a bias node, the method comprising:
generating a reference voltage; and
applying the reference voltage to the bias node to provide a controlled current through the first inverter.

9. The method of claim 8, wherein applying the reference voltage comprises applying the reference voltage via a resistor coupled to the bias node and coupling a voltage at the input node to the bias node via a capacitor.

10. The method of claim 8, wherein generating the reference voltage comprises generating the reference voltage with a bandgap circuit.

11. The method of claim 9, wherein the resistor comprises at least one transistor biased in a cutoff region.

12. The method of claim 8, further comprising generating a dead zone region in a DC transfer characteristic of the plurality of serially coupled inverters using a resistor, transistor or diode circuit coupled to an intermediate inverter of the plurality of serially coupled inverters.

13. A system comprising:
a first ring amplifier comprising a first bias node; and
a reference current source coupled to the first bias node to provide a controlled current through a first inverter of the first ring amplifier.

14. The system of claim 13, further comprising:
a first resistor interposed between the reference current source and the first bias node; and
a first filter capacitor coupled between the first bias node and a first input node.

15. The system of claim 14, further comprising a first input capacitor coupled to the first input node, and a first adjustable feedback capacitor coupled between the first input node and an output node of the first ring amplifier.

16. The system of claim 15, further comprising a first adjustable analog-to-digital converter (ADC) input capacitor coupled to the output node of the first ring amplifier.

17. The system of claim 13 further comprising a second ring amplifier comprising a second bias node coupled to the reference current source to provide a stable current through the first inverter of the second ring amplifier.

18. The system of claim 17, further comprising a chopper coupled to a first input node of the first ring amplifier and to a second input node of the second ring amplifier.

19. The system of claim 18, further comprising a first source follower circuit and a second source follower circuit coupled to the chopper.

20. The system of claim 19, further comprising a microelectromechanical system (MEMS) device coupled to the first source follower circuit and to the second source follower circuit.
